(19) United States
(12) Patent Application Publication
(10) Pub. No.: US 2016/0299424 A1
(43) Pub. Date: Oct. 13, 2016

(54) DIE WITH A DIE STRUCTURE AS WELL AS METHOD FOR ITS PRODUCTION

(71) Applicant: EV GROUP E. THALLNER GMBH, St. Florian am Inn (AT)

(72) Inventor: Mustapha CHOUIKI, Linz (AT)

(73) Assignee: EV GROUP E. THALLNER GMBH, St. Florian am Inn (AT)

(21) Appl. No.: 15/035,568

(22) PCT Filed: Nov. 29, 2013
(86) PCT No.: PCT/EP2013/075113

§ 371 Date: May 10, 2016

(51) Int. Cl. G03F 7/00; B41K 3/36

(52) U.S. Cl. CPC G03F 7/0002; B41K 3/36

(57) ABSTRACT

A method for the production of a structural die that has die structures for applying microstructures and/or nanostructures on substrates or soft dies, whereby the die structures are comprised at least partially of a die material with low adhesion properties.

The invention relates to a method for the production of a die that has die structures according to claim 6, as well as a structural die according to claim 1.

In the semiconductor industry, structuring processes must be carried out on materials in order to be able to produce corresponding functional elements. One of the most important structuring processes of the last decade up until now is still photolithography.

In recent years, however, in addition to photolithography, imprint technology has gained acceptance as a new, alternative structuring technology, which is used not exclusively, but at this time if anything predominantly, for structuring highly symmetrical, primarily repetitive structural elements. By means of imprint technology, surface structures in an embossing material can be created directly by a die process. The advantages that are thus produced are obvious. Chemicals for development and etching that would still be necessary for a photolithographic process can be eliminated. In addition, even now structural values in the nanometer range can be embossed; their production with conventional photolithography would be conceivable only by extremely complicated and, primarily, costly units.

In imprint technology, a distinction is made between two types of dies, the hard dies and the soft dies. Each die process can theoretically be carried out with a hard die or a soft die. There are several technical and financial reasons, however, for using the hard die itself only as a so-called master die and from this master die, whenever necessary, forming a soft die, which then is used as an actual structural die. The hard die is thus a negative of the soft die. The hard die is only required for the production of several soft dies. Soft dies can be distinguished from hard dies by different chemical, physical, and technical parameters. A distinction based on the elasticity behavior would be conceivable. Soft dies have a deformation behavior that is predominantly based on entropy elasticity, and hard dies have a deformation behavior that is predominantly based on energy elasticity. In addition, the two types of dies can be distinguished by, for example, their hardness. Hardness is the resistance that a material puts up against a penetrating body. Since hard dies predominantly consist of metals or ceramics, they have correspondingly high hardness values. There are various ways of indicating the hardness of a solid. A very common method is the indication of the hardness according to Vickers. Without going into detail, it can be roughly stated that hard dies are to have Vickers hardness values of beyond 500 HV.

Hard dies specifically have the advantage that they can be directly manufactured by suitable processes such as electron beam lithography or laser beam lithography from a component made of a material with high strength and a high degree of stiffness. Such hard dies have a very high degree of hardness and are thus more or less wear-resistant. The high strength and wear resistance, however, are offset primarily by the high costs that are incurred for producing such a hard die. Even though the hard die can be used for hundreds of embossing steps, even it will experience significant wear and tear over time. In addition, the demolding of the hard die from the embossing material is technically difficult. Hard dies have a relatively high bending resistance. They are not especially well deformable, i.e., they have to be lifted off in the normal direction to the embossing surface. In the demolding of the hard die after the embossing process, in this case it can regularly result in a destruction of the embossed nanostructures and/or microstructures, since the hard die has a very high degree of stiffness and therefore can destroy the microstructures and/or nanostructures of the just-molded embossing material. In addition, substrates can have defects that can subsequently lead to damage or destruction of the hard die. If the hard die is only used as a master die, however, the molding process of the soft die from the master die is very well controllable and is associated with very little wear of the master die.

Soft dies can be manufactured very simply by replication processes from the master die (hard die). In this case, the master die represents the negative that corresponds to the soft die. The soft dies are thus embossed on the master die, subsequently demolded, and then are used as structural dies for embossing the die structures in an embossing material, which in most cases is applied on a substrate. Soft dies can be mechanically removed more simply, gently and less problematically from the embossing material than hard dies. In addition, any number of soft dies can be molded by a master die. After a soft die has undergone a certain wear, the soft die is discarded and a new die is formed from the master die.

The problem with the current state of the art consists in that primarily soft dies have a very high absorbency of other molecular compounds because of their chemical design. They are thus permeable in general to other molecular compounds, in contrast to hard dies that consist predominantly of metals, ceramics, or glass. In the case of metal and ceramic microstructures, an uptake of molecular substances is ruled out in most cases, since even in the case of special hard dies, it can result in an absorption of molecular substances.

During the embossing process with the embossing material, soft dies often absorb a portion of the embossing material. The absorption leads to several undesirable effects.

First of all, because of the uptake of molecules of the embossing material, it results in a swelling of the soft die. The swelling is primarily problematic in the area of the microstructures and/or nanostructures on the surface of the soft die, since even small amounts of the molecules of the embossing material are sufficient to distort the microstructures and/or nanostructures. Since a soft die is used many times, it absorbs an increasing amount of embossing material molecules in the course of its use. The uptake of embossing material molecules decisively reduces the service life of the soft die. The swelling can be measured either directly by means of different probes, such as, for example, the Atomic Force Microscopy (AFM), the Scanning Electron Microscopy (SEM), etc., or indirectly via increases in volume and/or weight. The measurement of the increase of volume and/or weight requires, however, measuring devices with very high resolutions. For example, the measurement of the weight increase by microgravimetric and/or nanogravimetric methods would be conceivable.

In addition, the embossing materials are hardened either thermally or by means of electromagnetic radiation. Primarily in the hardening by electromagnetic radiation, the embossing material molecules that have already partially penetrated into the die have a negative effect on the exposure time of the entire embossing material. The reason for this lies in the hardening of the embossing material molecules that have penetrated into the soft die. The embossing material molecules in the soft die are hardened, are thus less transparent, and thus reduce the intensity of the electromagnetic radiation that penetrates the actual embossing material. This problem is equally important for soft dies and hard dies.

The adhesion of the soft die represents a third problem. Soft dies consist predominantly of polymers, which have physical and/or chemical properties that are similar to those of the embossing material. Therefore, it results in an adhesion of the surface of the soft die with the embossing material, which has a negative effect on the demolding property of the soft die.

The object of this invention is therefore to improve the production of structural dies for imprint technology in such a way that an optimal die material is disclosed.

This object is achieved with the features of claims 1 and 6. Advantageous further developments of the invention are indicated in the subclaims. All combinations that consist of at least two of the features indicated in the specification, the claims and/or the figures also fall within the scope of the invention. In the case of the indicated ranges of values, values that lie within the above-mentioned limits are also to be regarded as disclosed as boundary values and can be claimed in any combination.

The invention involves a die, preferably a soft die, which consists of a die material that allows a demolding of the die from the embossing material that is as simple as possible, that has as little swelling as possible, and that is not contaminated by the actual embossing material. The die material is accordingly especially impermeable according to the invention relative to the embossing material. In general, it is of special advantage according to the invention when hydrophilicity and hydrophobicity alternate between the embossing material and the die material of the structural die according to the invention. If the embossing material is hydrophobic, the die material of the structural die according to the invention should be hydrophilic and vice versa. In quite special cases, however, it may be of special advantage when structural dies and embossing materials are both hydrophobic or both hydrophilic. Because of the possibility of selecting the die material of the structural die according to the invention, a material can always be selected that has these low adhesion properties relative to the embossing material. In addition, it is therefore advantageous according to the invention when the die material according to the invention is impermeable to the molecules of the embossing material. Another advantage according to the invention is the, especially specifically adjustable, surface of the die material according to the invention. Primarily in the case of a soft die, whose surface has an extremely high level of roughness, this would have a negative effect on the structure that is to be embossed. By using a die material according to the invention, first of all, the contact surface with the embossing material is now minimized by a smoother surface, and secondly, a positive connection is reduced. Thus, it also results in an enhanced demolding. The enhanced and more efficient demolding is primarily attributed to the fact that the force necessary for demolding is lower. The roughness of the die material according to the invention is therefore less than 1 μm, preferably less than 100 nm, more preferably less than 10 nm, and most preferably less than 1 nm. The disclosed roughness values apply to the mean roughness and/or the quadratic roughness and/or the averaged depth of roughness. In this case, the measurement is done with a surface section of approximately 2 μm×2 μm.

In a quite special embodiment, the die material according to the invention is electrically conductive. As a result, the electrostatic charging is preferably prevented or at least reduced. Still more preferably, the electrically conductive die material according to the invention can be grounded so that a charging that is produced on its surface is drawn off. Because of the electrically neutral surface, the force, in particular the electrostatic force, is hampered by particles or completely eliminated and thus increases the cleanliness of the die over an extended period. The ground brings into contact the die material according to the invention and thus the die, preferably at the edge. The electrical conductivity of the die material can be produced either by a chemical structure that is used in a targeted manner and that already allows a conductivity of electrons because of the molecular property thereof, or by the addition of at least one additional component, which makes the non-conductive die material conductive. Especially preferred in this case is the use of microparticles and/or nanoparticles, nanowires, in particular carbon nanotubes, graphene, graphite, etc. The added microparticles and/or nanoparticles can also be used especially preferably for heating the die if the hardening of the embossing material takes place thermally and not, as actually preferred, by means of UV light. Such a heating by microparticles and/or nanoparticles was disclosed in the patent specification EP 2286981B1. However, the cited patent specification makes reference to the fact that the microparticles and/or nanoparticles are located in the embossing material. In this application, the microparticles and/or nanoparticles would be located in the die material according to the invention in order to achieve a direct heating of the die and not the embossing material. The heating of the embossing material is then carried out indirectly via the die. As in the patent specification EP 2286981B1, it would be conceivable to heat the microparticles and/or the nanoparticles by means of an alternating magnetic field; if the microparticles and/or nanoparticles are sensitive to the magnetic field, they are therefore magnetic.

Hydrophilicity is defined as the high capacity of the surface of a substance for interaction with water. Hydrophilic surfaces are predominantly polar and interact correspondingly well with the permanent dipoles of the molecules of fluids, preferably with water. The hydrophilicity of a surface is quantified by means of a contact angle measuring device. In this case, hydrophilic surfaces have very small contact angles. If the coating according to the invention must have a hydrophilic surface in order to be able to be demolded as easily as possible from the embossing material, then the following ranges of values according to the invention apply: A hydrophilic surface has a contact angle of less than 90°, preferably less than 60°, more preferably less than 40°, even more preferably less than 20°, and with utmost preference less than 10°.

Hydrophobicity correspondingly is defined as the low capacity of the surface of a substance for interaction with water. Hydrophobic surfaces are predominantly nonpolar and hardly interact with the permanent dipoles of the molecules of fluids. If the coating according to the invention in one embodiment of the invention has a hydrophobic surface in order to be able to be removed as simply as possible from the embossing material, then the following ranges of values according to the invention are to apply: a hydrophobic surface has a contact angle of greater than 90°, preferably greater than 100°, more preferably greater than 120°, even more preferably greater than 140°, and with utmost preference greater than 160°. Although the behavior of a surface relative to water is characterized by means of the hydrophilicity or hydrophobicity, it is clear to any one skilled in the art that the adhesion properties between different materials must be measured directly in order to obtain exact information on their mutual behavior. The characterization of the adhesion properties of a surface relative to water already delivers, however, very great insight into the adhesion behavior. In the characterization of the adhesion property between a die material and an embossing material, the contact angle measuring method according to the invention is not performed with water, but rather directly with a drop of the embossing material, which is deposited directly on the die.

The die according to the invention is in particular an imprint die for use in imprint technology. The die is designed either as a hard die for production of soft dies or preferably as a soft die for imprinting substrates. Because of the die material according to the invention, the demolding of the die from the embossing material is made possible without impairing and/or (partially) destroying the structures by the die preferably having a slight adhesion relative to the embossing material. The adhesiveness between two surfaces can be best described by energy per unit surface, i.e., an energy surface density. This refers to the energy that is necessary to once again separate from one another two surfaces, connected to one another, along the unit surface. The adhesion between embossing material and structural die is in this case less than 2.5 J/m², preferably less than 1 J/m², more preferably less than 0.1 J/m², even more preferably less than 0.01 J/m², most preferably less than 0.001 J/m², with utmost preference less than 0.0001 J/m², and most preferably less than 0.00001 J/m² The demolding is thus easier, faster, and more efficient and more economically possible than with a die that does not use the die material according to the invention. It is more economical primarily in that because of the elevated demolding speed, the number of embossing steps per unit of time can be increased. In addition, the service life of the die is drastically increased, so that in this respect, the production costs are also reduced.

Preferably, a die material is used whose sealing is so substantial that a swelling of the structural die, in particular the soft die, is prevented by the structural material according to the invention, since no embossing material can penetrate into the soft die. Correspondingly, a distortion of the die structure is avoided to the greatest possible extent.

The die material preferably has a viscosity of between 1 and 2,500 mPas, preferably between 10 and 2,500 mPas, more preferably between 100 and 2,500 mPas, and most preferably between 150 and 2,500 mPas.

In addition, the exposure time of the embossing material is to be reduced by the die material of the die, insofar as the uptake of embossing material is blocked or at least reduced by the die material according to the invention. This is primarily necessary when the embossing material is exposed by the structural die. The embossing material according to the invention is thus preferably predominantly transparent to the electromagnetic radiation that is used. Since most embossing materials are hardened with UV light, the die material according to the invention is preferably transparent to UV light. The die material according to the invention is in particular transparent in a wavelength range of between 5,000 nm and 10 nm, preferably between 1,000 nm and 100 nm, more preferably between 700 nm and 200 nm, and most preferably between 500 nm and 300 nm.

The die material according to the invention, the die structures and/or the structural die itself consist in particular at least predominantly, preferably completely, of at least one of the following materials:

Silicones,

Vinyl-functional polymers
Vinyl-terminated polydimethylsiloxanes, in particular CAS: 68083-12-2
Vinyl-terminated diphenylsiloxane-dimethylsiloxane copolymers, in particular CAS: 68951-96-2
Vinyl-terminated polyphenylmethylsiloxanes, in particular CAS: 225927-21-9
Vinylphenyl-methyl-terminated vinylphenylsiloxane-phenylmethylsiloxane copolymer, in particular CAS: 8027-82-1
Vinyl-terminated trifluoropropylmethylsiloxane-dimethylsiloxane copolymer, in particular CAS: 68951-98-4
Vinylmethylsiloxane-dimethylsiloxane copolymer, trimethylsiloxy-terminated, in particular CAS: 67762-94-1
Vinylmethylsiloxane-dimethylsiloxane copolymer, silanol-terminated, in particular CAS 67923-19-7
Vinylmethylsiloxane-dimethylsiloxane copolymer, vinyl-terminated, in particular CAS: 68083-18-1
Vinyl rubber
Vinyl Q resin dispersions, in particular CAS: 68584-83-8
Vinylmethylsiloxane homopolymers, in particular CAS: 68037-87-6
Vinyl T-structure polymers, in particular CAS: 126681-51-9
Monovinyl-functionalized polydimethylsiloxane that is symmetrical or asymmetrical, in particular CAS: 689252-00-1
Vinylmethylsiloxane terpolymers, in particular CAS: 597543-32-3
Vinylmethoxysiloxane homopolymer, in particular CAS: 131298-48-1
Vinylethoxysiloxane homopolymer, in particular CAS: 29434-25-1
Vinylethoxysiloxane-propylethoxysiloxane copolymer

Hydride-functional polymers
Hydride-terminated polydimethylsiloxanes, in particular CAS: 70900-21-9
Polyphenylmethylsiloxane, hydride-terminated
Methylhydrosiloxane-dimethylsiloxane copolymer, trimethylsiloxy-terminated, in particular CAS: 68037-59-2
Methylhydrosiloxane-dimethylsiloxane copolymer, hydride-terminated, in particular CAS: 69013-23-6
Polymethylhydrosiloxane, trimethylsiloxy-terminated, in particular CAS: 63148-57-2
Polyethylhydrosiloxane, triethylsiloxy-terminated, in particular CAS: 24979-95-1
Polyphenyl-dimethylhydrosiloxysiloxane, hydride-terminated
Methylhydrosiloxane-phenylmethylsiloxane copolymer, hydride-terminated, in particular CAS: 115487-49-5
Methylhydrosiloxane-octylmethylsiloxane copolymer and terpolymer, in particular CAS: 68554-69-8
Hydride Q resin, in particular CAS: 68988-57-8

Silanol-functional polymers
Silanol-terminated polydimethylsiloxane, in particular CAS: 70131-67-8
Silanol-terminated diphenylsiloxane-dimethylsiloxane copolymer, in particular CAS 68951-93-9 and/or CAS: 68083-14-7
Silanol-terminated polydiphenylsiloxane, in particular CAS: 63148-59-4
Silanol-terminated polytrifluoropropylmethylsiloxane, in particular CAS: 68607-77-2
Silanol-trimethylsilyl-modified Q resin, in particular CAS: 56275-01-5

Amino-functionalized silicones
Aminopropyl-terminated polydimethylsiloxane, in particular CAS: 106214-84-0
N-Ethylaminoisobutyl-terminated polydimethylsiloxane, in particular CAS: 254891-17-3
Aminopropyl methylsiloxane-dimethylsiloxane copolymer, in particular CAS: 99363-37-8
Aminoethyl aminopropyl methylsiloxane-dimethylsiloxane copolymer, in particular CAS 71750-79-3
Aminoethyl aminoisobutyl methylsiloxane-dimethylsiloxane copolymer, in particular CAS: 106842-44-8
Aminoethyl aminopropyl methoxy siloxane-dimethylsiloxane copolymer, in particular CAS: 67923-07-3

Hindered amine-functional siloxanes (engl.: hindered amine-functional siloxanes)
Tetramethylpiperidinyloxypropylmethylsiloxane-dimethylsiloxane copolymer, in particular CAS: 182635-99-0

Epoxy-functionalized silicones
Epoxypropoxy propyl-terminated polydimethylsiloxanes, in particular CAS: 102782-97-8
Epoxypropoxy propyl methylsiloxane-dimethylsiloxane copolymer, in particular CAS: 68440-71-7
Epoxypropoxy propyl-terminated polyphenylmethylsiloxane, in particular CAS: 102782-98-9
Epoxypropoxy propyldimethoxysilyl-terminated polydimethylsiloxanes, in particular CAS: 188958-73-8
Tris(glycidoxypropyldimethylsiloxy)phenylsilane, in particular CAS: 90393-83-2
Mono-(2,3-epoxy)-propylether-terminated polydimethylsiloxanes (preferred embodiment), in particular CAS: 127947-26-6
Epoxycyclohexylethylmethylsiloxane-dimethylsiloxane copolymer, in particular CAS: 67762-95-2
(2-3% Epoxycyclohexylethylmethylsiloxane) (10-15% methoxypolyalkyleneoxymethylsiloxane)-dimethylsiloxane terpolymer, in particular CAS: 69669-36-9

Cycloaliphatic Epoxysilanes and Silicones
Epoxycyclohexylethylmethylsiloxane-dimethylsiloxane copolymer, in particular CAS: 67762-95-2
(2-3% Epoxycyclohexylethylmethylsiloxane) (10-15% methoxypolyalkyleneoxymethylsiloxane)-dimethylsiloxane terpolymer, in particular CAS: 69669-36-9
Epoxycyclohexylethyl-terminated polydimethylsiloxanes, in particular CAS: 102782-98-9

Carbinol-functionalized silicones
Carbinol(hydroxyl)-terminated polydimethylsiloxanes, in particular CAS: 156327-07-0, CAS: 104780-66-7, CAS: 68937-54-2, CAS: 161755-53-9, CAS: 120359-07-b 1
Bis(Hydroxyethyl)amine)-terminated polydimethylsiloxanes
Carbinol-functionalized methylsiloxane-dimethylsiloxane copolymers, in particular CAS: 68937-54-2, CAS: 68957-00-6, CAS: 200443-93-2
Monocarbinol-terminated polydimethylsiloxanes, in particular CAS: 207308-30-3
Monodicarbinol-terminated polydimethylsiloxanes, in particular CAS: 218131-11-4

Methacrylates and acrylate-functionalized siloxanes
Methacryloxypropyl-terminated polydimethylsiloxanes, in particular CAS: 58130-03-3
(3-Acryloxy-2-hydroxypropoxypropyl)-terminated polydimethylsiloxanes, in particular CAS: 128754-61-0
Acryloxy-terminated ethylene oxide-dimethylsiloxane-ethylene oxides ABA block copolymers, in particular CAS: 117440-21-9
Methacryloxypropyl-terminated branched polydimethylsiloxanes, in particular CAS: 80722-63-0
Methacryloxypropylmethylsiloxane-dimethylsiloxane copolymer, in particular: CAS: 104780-61-2
Acryloxypropylmethylsiloxane-dimethylsiloxane copolymer, in particular CAS: 158061-40-6
(3-Acryloxy-2-hydroxypropoxypropyl)methylsiloxane-dimethylsiloxane copolymer
Methacryloxypropyl T-structured siloxanes, in particular CAS: 67923-18-6
Acryloxypropyl T-structured siloxanes

Polyhedral oligomeric silsesquioxane (POSS)

Tetraethyl orthosilicate (TEOS)

Poly(organo)siloxanes

The die material preferably consists of an epoxy-silicone and/or an acrylate-silicone. The chemical basic structure of the die material according to the invention is therefore a polydimethylsiloxane, in which methyl groups were replaced by epoxide groups and/or acrylate groups at regular or irregular intervals. These chemical groups preferably allow the hardening of the die material according to the invention by means of UV light. To start the UV-hardening process, corresponding radical and/or cation starters can be added to the die material according to the invention.

In addition, it is conceivable to produce the dies, in particular the die structures, from a material combination of the above-mentioned materials. The use of a die and a backplane in series is also conceivable, whereby dies and backplanes in general consist of different materials. The use of several different materials leads to the individual or composite dies produced therefrom being referred to as hybrid dies. In this case, the backplane can serve as a stiffener of the die. Backplanes that are extremely flexible and serve only as supports for the dies are also conceivable, however. The backplane then has in particular a thickness that is less than 2,000 μm, preferably less than 1,000 μm, more preferably less than 500 μm, and most preferably less than 100 μm.

In an especially preferred embodiment, the die is coated with an anti-adhesive layer in order to achieve in addition a reduction of the adhesion between die material and embossing material according to the invention. The anti-adhesive layer is preferably an organic molecule with correspondingly low adhesion properties for the embossing material. Should the die already be impermeable to the molecule of the embossing material, just as is the case for the most part for, for example, metal, ceramic or glass dies, a coating according to the invention as a diffusion barrier can be eliminated, and the die can be directly coated with an anti-adhesive layer, in this case as a coating according to the invention. Thus, at least one positive effect relative to the demolding property is produced based on adhesion. Such a coating was already mentioned in the patent specification PCT/EP2013/062922, to which reference is made in this respect.

In the UV hardening of the embossing material, the die material according to the invention is preferably at least partially transparent for the wavelength range of the electromagnetic radiation, which the embossing material cross-links. In this case, the optical transparency is greater than 0%, preferably greater than 20%, more preferably greater than 50%, most preferably greater than 80%, and with utmost preference greater than 95%. The wavelength range for the optical transparency has a value of in particular between 100 nm and 1,000 nm, preferably between 150 nm and 500 nm, more preferably between 200 nm and 400 nm, and most preferably between 250 nm and 350 nm.

If the embossing material is to be thermally hardened, the die—in particular the coating according to the invention—has a heat conductivity that is as high as possible. In this case, the heat conductivity is greater than 0.1 W/(m*K), preferably greater than 1 W/(m*K), preferably greater than 10 W/(m*K), most preferably greater than 100 W/(m*K), and with utmost preference greater than 1,000 W/(m*K).

The structural die with a coating is designed in particular to be temperature-stable. The structural die can be used in particular at temperatures of higher than 25° C., preferably higher than 100° C., more preferably higher than 250° C., most preferably higher than 500° C., and with utmost preference higher than 750° C.

The E-modulus characterizes the elasticity of a material. In principle, the structural die can have any E-modulus. Preferable, however, are the smallest E-moduli possible in order to keep the structural die deformable and thus to be able to separate it more easily from the embossing material. The elasticity is predominantly an entropy elasticity. The E-modulus is therefore in particular smaller than 10,000 MPa, preferably smaller than 1,000 MPa, more preferably smaller than 100 MPa, most preferably between 1 and 50 MPa, and with utmost preference between 1 and 20 MPa.

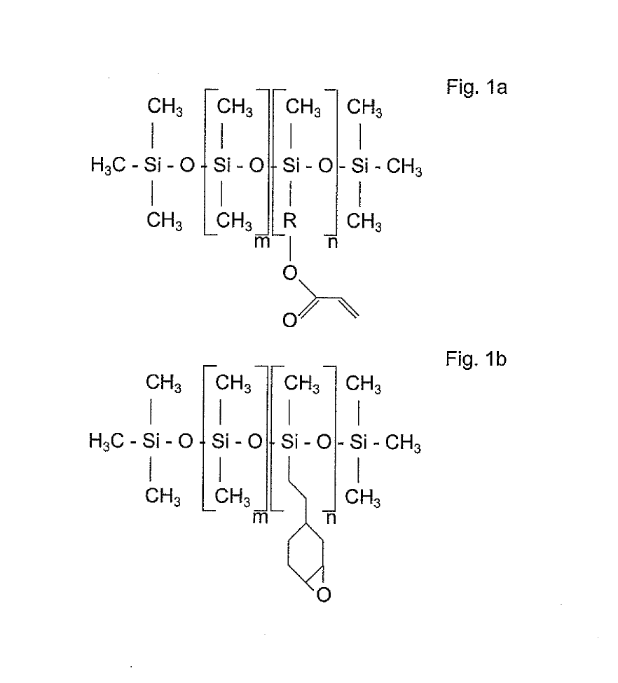

FIG. 1a shows the chemical structural formula of a preferred acrylate silicone, and

FIG. 1b shows the chemical structural formula of a preferred epoxy silicone.

1-7. (canceled)

8. Imprint die with a die structure, wherein the die structure is formed at least partially from a silicone as a die material, the die being deformable and having an E-Modulus smaller than 10,000 MPa.

9. Die according to claim 8, wherein the die material has epoxy and/or acryl groups.

10. Die according to claim 8, wherein the die material is formed from one or more of the following materials:
acrylate or epoxy silicone,
polyhedral oligomeric silsesquioxane (POSS),
tetraethyl orthosilicate (TEOS), and/or
poly(organo)siloxanes.

11. Die according to claim 8, wherein the die material is hardened or can be hardened by UV radiation or by thermal irradiation.

12. Die according to claim 8, wherein the die material is transparent in a wavelength range of between 5000 nm and 10 nm.

13. Method for producing a die structure of an imprint die, wherein the method comprises:
forming the die structure at least partially from a silicone as die material,
wherein the die is deformable and has an E-Modulus smaller than 10,000 MPa.

14. Method according to claim 13, wherein the method further comprises:
hardening the die material of the die structure by UV irradiation or by thermal irradiation.

15. Die according to claim 12, wherein the die material is transparent in a wavelength range of between 1000 nm and 100 nm.

16. Die according to claim 12, wherein the die material is transparent in a wavelength range of between 700 nm and 200 nm.

17. Die according to claim 12, wherein the die material is transparent in a wavelength range of between 500 nm and 400 nm.
